(19) United States
(12) Patent Application Publication
(10) Pub. No.: US 2009/0186450 A1
(43) Pub. Date: Jul. 23, 2009

(54) IC PACKAGING PROCESS BY PHOTO-CURING ADHESIVE

(75) Inventor: Chung-Mao Yeh, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: LINGSEN PRECISION INDUSTRIES, LTD, Taichung (TW)

(21) Appl. No.: 12/263,262

(22) Filed: Oct. 31, 2008

(30) Foreign Application Priority Data
Jan. 18, 2008 (TW) 97102060

(51) Int. Cl. H01L 21/00

(52) U.S. Cl. 438/118; 257/E23.01

(57) ABSTRACT

A IC packaging process includes the steps of mounting at least one retaining member on a top side of a substrate, the retaining member defining a receiving space, a chip being mounted to the substrate and located in the receiving space; forming a photo-curing adhesive layer in the receiving space, the photo-curing adhesive layer being capable of shielding the chip completely; irradiating and developing the photo-curing adhesive layer to harden a part of the photo-curing adhesive layer to define a hardened portion thereof, the other part of the photo-curing adhesive layer defining a non-hardened portion corresponding to the chip; and removing the non-hardened portion to expose an active portion of the chip.

### BACKGROUND OF THE INVENTION

1. Field of the Invention

The present invention relates generally to semiconductor, and more particularly, to an IC packaging process by photo-curing adhesive.

2. Description of the Related Art

Referring to FIG. 6, a conventional IC packaging process includes the steps of mounting at least one retaining member 1 on a top side of a substrate 2, the retaining member 1 defining a receiving space 3, a chip 4 being mounted to the substrate 2 and located in the receiving space 3; coating photo-curing adhesive 5 on a top side of the retaining member 1; mounting a cover member 6 on a top side of the retaining member 1 to seal the receiving space 3; and irradiate the photo-curing adhesive 5 to harden and enable the photo-curing adhesive 5 to be fixed to the retaining member 1 and the cover member 6.

However, the cover member 6 is generally made of glass to be liable to damage incurred by an external impact. In other words, the cover member 6 is limited in structural strength, failing to securely protect the chip 4. Further, if it is intended to enhance the structural strength of the cover member 6 by increasing the thickness of the cover member 6, it will adversely influence the operating performance of the chip 4. Besides, if the thickness of the retaining member 1 is increased to enhance the structural strength thereof, the whole size and production cost will be increased.

### SUMMARY OF THE INVENTION

The primary objective of the present invention is to provide an IC packaging process by photo-curing adhesive, which can enhance the whole structural strength to securely protect the chip.

The foregoing objective of the present invention is attained by the IC packaging process includes the steps of mounting at least one retaining member on a top side of a substrate, the retaining member defining a receiving space, a chip being mounted to the substrate and located in the receiving space; forming a photo-curing adhesive layer in the receiving space, the photo-curing adhesive layer being capable of shielding the chip completely; irradiating and developing the photo-curing adhesive layer to harden a part of the photo-curing adhesive layer to define a hardened portion thereof, the other part of the photo-curing adhesive layer defining a non-hardened portion corresponding to the chip; and removing the non-hardened portion to expose an active portion of the chip.

In light of the above steps, the present invention provides greater rigidity and adhesion than the prior art did to effectively enhance the whole structural strength, thus securely protecting the chip. In addition, the photo-curing adhesive layer shields the chip but does not obscure the active portion of the chip, such that the chip provides better operating performance than the prior art did. In addition, the photo-curing adhesive is more inexpensive than the glass, so the present invention can reduce the production cost.

### BRIEF DESCRIPTION OF THE DRAWINGS

FIG. 1 is a flow chart of a preferred embodiment of the present invention.

FIG. 2 is a sectional view, illustrating the first step of the preferred embodiment of the present invention.

FIG. 3 is a sectional view, illustrating the second step of the preferred embodiment of the present invention.

FIG. 4 is a sectional view, illustrating the third step of the preferred embodiment of the present invention.

FIG. 5 is a sectional view, illustrating the fourth step of the preferred embodiment of the present invention.

FIG. 6 shows the conventional IC packaging process.

### DETAILED DESCRIPTION OF PREFERRED EMBODIMENTS

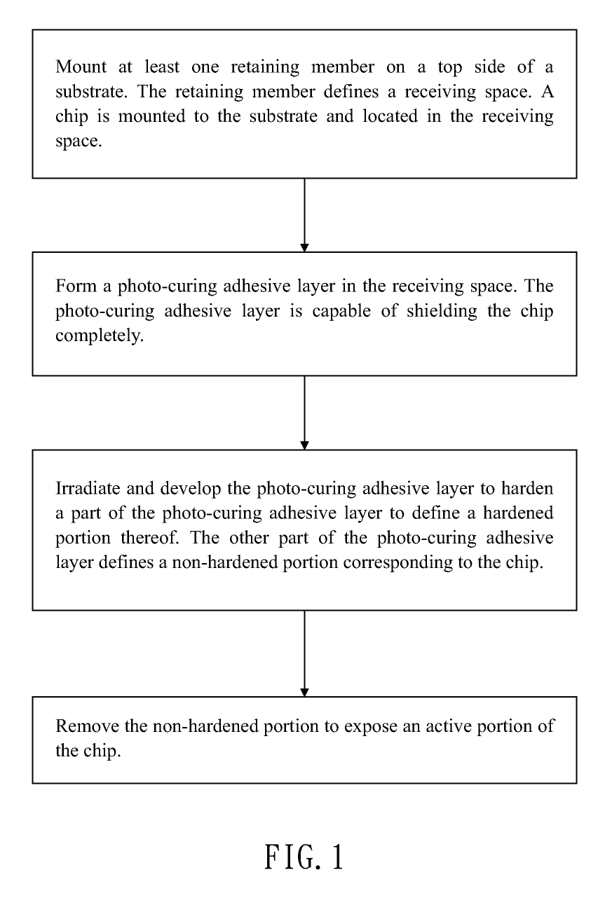

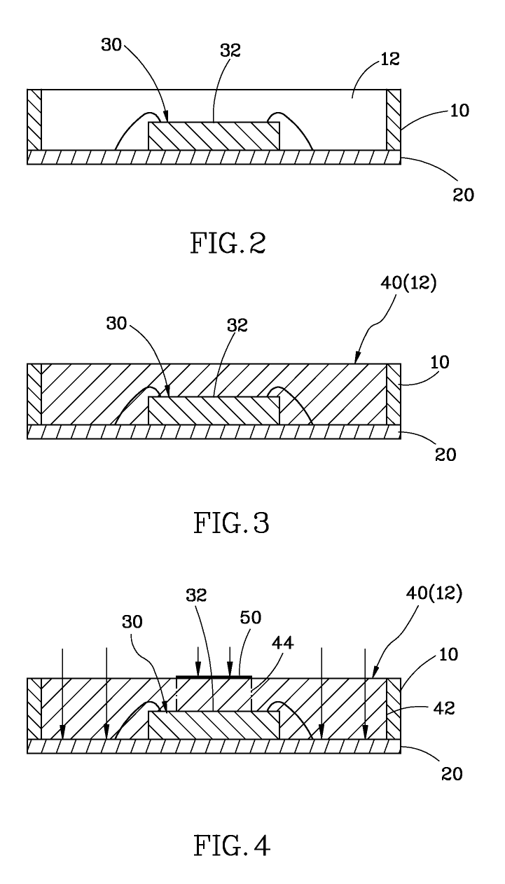

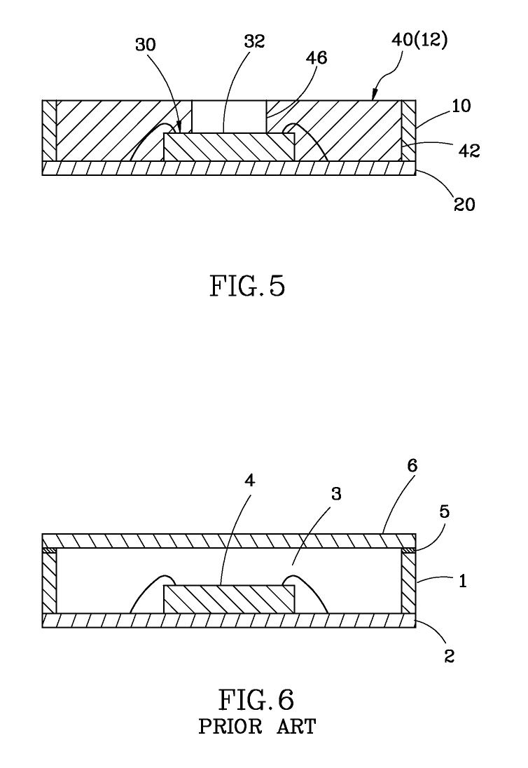

Referring to FIGS. 1-5, an IC packaging process by means of photo-curing adhesive in accordance with a preferred embodiment of the present invention includes the following steps.
A. Mount a retaining member 10 on a top side of a substrate 20, as shown in FIG. 2. The retaining member 10 defines a receiving space 12 above the substrate 20. A chip 30 is mounted to the substrate 20 and located in the receiving space 12.
B. Fill the receiving space 10 with photo-curing adhesive to form a photo-curing adhesive layer 40 completely shielding the chip 30, as shown in FIG. 3. In the meantime, the photo-curing adhesive layer 40 is colloid.
C. Irradiating and developing the photo-curing adhesive layer 40 to harden a part of the photo-curing adhesive layer 40 to define a hardened portion 42 thereof. The other part of the photo-curing adhesive layer 40 defines a non-hardened portion 44 corresponding to the photo-curing adhesive layer 40. This step includes the following sub-steps.
   C1. Place a jig 50 on a top side of the photo-curing adhesive layer 40. The jig 50 is covered over the chip 30.
   C2. Irradiate the photo-curing adhesive layer 40. The hardened portion 42 is the part of the photo-curing adhesive layer 40 that is not shielded by the jig 50. The non-hardened portion 44 is the part of the photo-curing adhesive layer 40 that is shielded by the jig 50.
D. Remove the jig 50 and then the non-hardened portion 44 to form a hole 46 and to expose an active portion 32 of the chip 30. In this embodiment of the present invention, the non-hardened portion 44 is removed by etching.

In light of the above steps of the present invention, the photo-curing adhesive layer 40 provides greater rigidity and adhesion than the prior art did, such that the present invention overcomes the drawback of the prior art that the whole structural strength is deficient. In other words, the present invention can enhance the whole structural strength to securely protect the chip, whereby the chip can provide better operating performance. In addition, the photo-curing adhesive of the present invention is more inexpensive than the glass that the cover member of the conventional IC packaging process is made.

Although the present invention has been described with respect to a specific preferred embodiment thereof, it is no way limited to the details of the illustrated structures but changes and modifications may be made within the scope of the appended claims.

What is claimed is:

1. An IC packaging process by photo-curing adhesive, comprising steps of:
(A) mounting at least one retaining member on a top side of a substrate, said retaining member defining a receiving space above said substrate, a chip being mounted to said substrate and located in said receiving space;
(B) forming a photo-curing adhesive layer in said receiving space, said photo-curing adhesive layer completely shielding said chip;
(C) irradiating and developing said photo-curing adhesive layer to harden a part of said photo-curing adhesive layer to define a hardened portion thereof, the other part of said photo-curing adhesive layer defining a non-hardened portion corresponding to said chip; and
(D) removing said non-hardened portion to expose an active portion of said chip.

2. The IC packaging process as defined in claim 1, wherein the step (C) includes sub-steps of:
(C1) placing a jig on a top side of said photo-curing adhesive layer, said jig being covered over said chip; and
(C2) irradiating said photo-curing adhesive layer to define said hardened portion, which is not shielded by said jig, and said non-hardened portion, which is shielded by said jig.

3. The IC packaging process as defined in claim 2, wherein the step (D) further includes a sub-step of removing said jig after removing said hardened portion.

4. The IC packaging process as defined in claim 1, wherein said hardened portion in the step (D) is removed by etching.
